(19) United States
(12) Patent Application Publication
(10) Pub. No.: US 2002/0182829 A1
(43) Pub. Date: Dec. 5, 2002

(54) Method for forming nitride read only memory with indium pocket region

(76) Inventor: Chia-Hsing Chen, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/870,530

(22) Filed: May 31, 2001

(51) Int. Cl. H01L 21/425

(52) U.S. Cl. 438/514; 438/517

(57) ABSTRACT

First of all, a P-type semiconductor substrate is provided. Then an oxide-nitride-oxide layer is formed on the P-type semiconductor substrate. Afterward, a photoresister layer is formed on the oxide-nitride-oxide layer, and it is defined to form a plurality of photoresister regions on the oxide-nitride-oxide layers. The oxide-nitride-oxide layer is then etched to form a plurality of nitride read only memory cells. Subsequently, perform a poketed implantation with indium ions to form a plurality of pocket dopant regions under a plurality of nitride read only memory cells, respectively. Next, perform a N-type ion-implanting process to form a plurality of ion-implanting regions in the P-type semiconductor substrate between a plurality of nitride read only memory cells. Finally, a plurality photoresister regions are removed to form an nitride read only memory.

### BACKGROUND OF THE INVENTION

1. Field of the Invention

The present invention relates generally to a method for forming a memory, and more particularly to a method for a read only memory.

2. Description of the Prior Art

Recently, developments have included various techniques for increasing the density of integration of the semiconductor memory device and decreasing the voltage thereof. A memory is a semiconductor device for using to store data or information, wherein the memory has plurality cells as plurality memory units for storing the data or information. The memory cells are arranged with array to connect with word line and bit line, so as to perform their function for reading or writing. There are two types of memory, one is random access memory (RAM) and another is read only memory (ROM). A random access memory is an array of latches, each with a unique address, having an addressing structure that is common for both reading and writing. Data stored in most types of RAM's is volatile because it is stored only as long as power is supplied to the RAM. Nevertheless, a read only memory is a circuit in which information is stored in a fixed, nonvolatile manner; that is, the stored information remains even when power is not supplied to the circuit.

By convention, the read only memories have various styles, which can be classed by different method for storing information, such as, a programmable read only memory (PROM) is one in which the information is stored after the device is fabricated and packaged, a erasable programmable read only memories (EPROM) are programmable read only memory that can be completely erased and reprogrammed, a electrically erasable programmable read only memories (EEPROM) and a mask read only memory (MROM). The mask read only memory is a device for programming a desired cell transistor by selectively implanting impurity ions into a channel region of the cell transistor in the course of fabricating the same. Once information is programmed, the information cannot be erased. Thus, it is a non-volatile memory.

A control gate and a floating gate have long been utilized for forming a memory. Electrons are moved onto or removed from the floating gate of a given memory cell in order to program or erase its state. The floating gate is surrounded by an electrically insulated dielectric. Since the floating gate is well insulated, this type of memory device is not volatile; that is, the floating gate retains its charge for an indefinite period without any power being applied to the device. Moreover, if enough electrons are so injected into the floating gate, the conductivity of the channel of the field effect transistor of which the floating gate is a part is changed. Hence, a control gate is coupled with the floating gate through a dielectric layer and acts as a word line to enable reading or writing of a single selected cell in a two-dimensional array of cells. One type of memory array integrated circuit chip includes elongated, spaced apart source and drain regions formed in a surface of a semiconductor substrate, wherein the source and drain regions form the bit lines of the memory. A two-dimensional array of floating gates has each floating gate positioned in a channel region between adjacent source and drain regions, while the control gate is positioned over each row of floating gates in a direction transverse to the source and drain regions, wherein the control gates are the word lines of the memory array.

If the read only memory has a structure, such as nitride layer, it is called nitride read only memory (NROM). There are two processes for fabricating the nitride read only memory (NROM) cells. In the first process, bit lines are first created in the substrate, after which the surface is oxidized. Following the oxidation, the ONO layers are added over the entire array. The word lines are then deposited with polysilicon in rows over the ONO layers. In the second process, the ONO layers are formed over the entire array first, on top of which conductive blocks of polysilicon are formed. The bit lines are implanted between the blocks of polysilicon after which the ONO layers are etched away from on top of the bit lines. Planarized oxide is then deposited between the polysilicon blocks after which polysilicon word lines are deposited.

In the conventional read only memory arrays, each programmed cell has a single threshold level throughout its channel, so that the cell has only one bit. Recently, the nitride read only memory has been developed for forming multi-bits. FIG. 1, to which reference is now made, schematically illustrates the nitride read only memory cell with dual bit.

The cell has a single channel 110 between two bit lines 120 and 130 in the semiconductor substrate 100 but two separated and separately chargeable areas 140 and 150. Each area defines one bit. For the dual bit cell of FIG. 1, the separately chargeable areas 140 and 150 are found within a nitride layer 160 formed in an oxide-nitride-oxide sandwich (layers 170, 160 and 180) underneath a polysilicon layer 190. To read the left bit, stored in area 140, right bit line 130 is the drain and left bit line 120 is the source. This is known as the “read through” direction. The cell is designed to ensure that, in this situation, only the charge in area 140 will affect the current in channel 110. To read the right bit, stored in area 150, the cell is read in the opposite direction. Thus, left bit line 120 is the drain and right bit line 130 is the source. Like floating gate cells, the cell of FIG. 1 is erasable and programmable. Thus, the charge stored in areas 140 and 150 can change over time in response to a user's request.

FIG. 2, to which reference is now made, schematically illustrates another nitride read only memory cell with dual bit. In the conventional nitride read only memory, each cell 200 comprises a channel 220 formed between two diffusion bit lines 230 in a substrate 210. Neighboring cells share bit lines 230. The substrate 210 is covered with a gate oxide layer 240. Polysilicon gates 250 and word lines cover the gate oxide layer 240. Each cell 200 is a dual bit cell whose left and right junctions 260 and 270, respectively, of the bit lines 230 with the channels 220 (e.g. “bit line junctions”) are separately programmable. When a bit is programmed, the edge of the channel 220 near the associated bit line junction is implanted with a threshold pocket implant. For unprogrammed bits, there is no implant and the threshold level of the junction remains the same as in the channel 220. To optimize the punchthrough of the implanted region, such as Boron, can be implanted into the junctions, and the threshold implant dosage is quite high. Unfortunately, implants of such high dosages tend to spread out in the channel and this reduces the cell's ability to punchthrough to the drain when reading the bit near the source. Furthermore, for scaled nitride read only memory and operation of more than two bit in per cell thereof, using the Boron ions as pocket dopant will increase pocket distribution and electron distribution in silicon nitride along the channel during hot electron programming. Therefore, the yield and quality of the process are decreased and, hence, increased cost.

In accordance with the above description, a new and improved method for forming the nitride read only memory is therefore necessary, so as to raise the yield and quality of the follow-up process.

### SUMMARY OF THE INVENTION

In accordance with the present invention, a method is provided for fabricating the read only memory that substantially overcomes drawbacks of above mentioned problems arised from the conventional methods.

Accordingly, it is a main object of the present invention to provide a method for fabricating the read only memory having multi-bits. This invention can use indium ions to implant, so as to substitute for boron ions and avoid defect of boron ions, which is easy to diffuse. Hence, the present invention is appropriate for deep sub-micron technology to provide the semiconductor devices.

Another object of the present invention is to provide a method for forming the nitride read only memory. The present invention can perform an ion-implanted process with the indium ions to form the pocket dopant region. This invention can much reduce the lateral distribution of pocket dopant with boron ions, due to the indium ions are difficult to diffuse. Furthermore, for scaled nitride read only memory devices and multi-bits per cell operation, pocket dopant of indium ions can reduce pocket distribution and, then, reduce the electron distribution in silicon nitride along the channel during hot electron programming. Hence, this invention can increase yield and quality, so that reduce process cost. Therefore, the present invention can correspond to economic effect. The process in this invention can uses the indium ions to perform the ion-implantion of the memory, so as to avoid defect of boron ions, which is easy to diffuse.

In accordance with the present invention, a new method for forming semiconductor devices is disclosed. First of all, a P-type semiconductor substrate is provided. Then an oxide-nitride-oxide layer is formed on the P-type semiconductor substrate. Afterward, a photoresister layer is formed on the oxide-nitride-oxide layer, and it is defined to form a plurality of photoresister regions on the oxide-nitride-oxide layers. The oxide-nitride-oxide layer is then etched by way of using a plurality of photoresister regions as a plurality of etching masks to form a plurality of nitride read only memory cells. Subsequently, perform the poketed implantation with indium ions by a plurality of photoresister regions as a plurality of implanted masks to form a plurality of pocket dopant regions under a plurality of nitride read only memory cells, respectively, wherein the indium ions can much reduce the lateral distribution of pocket dopant, due to the indium ions are difficult to diffuse, and that the pocket dopant of indium ions can reduce pocket distribution and, then, reduce the electron distribution in silicon nitride along the channel during hot electron programming. Next, perform a N-type ion-implanting process by way of using a plurality of photoresister regions as a plurality of implanted masks to form a plurality of ion-implanting regions in the P-type semiconductor substrate between a plurality of nitride read only memory cells. Finally, a plurality of photoresister regions are removed to form an nitride read only memory.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows cross-sectional views illustrative of structure in the conventional nitride read only memory having dual bits;

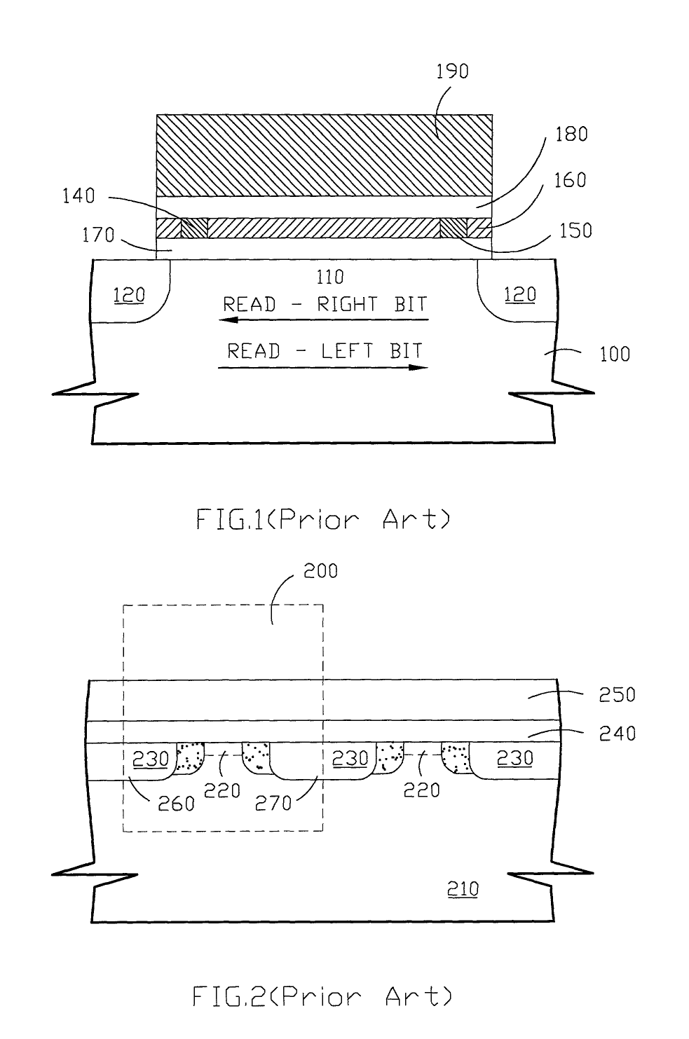

FIG. 2 shows cross-sectional views illustrative of structure in the conventional nitride read only memory having pocket dopant regions;

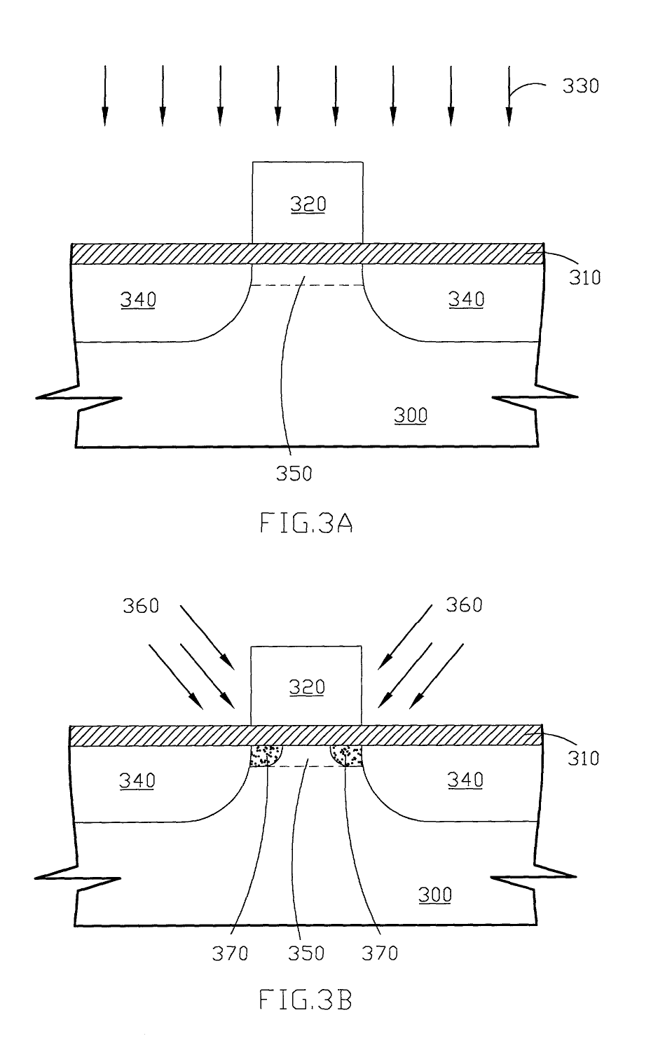

FIGS. 3A to 3C show cross-sectional views illustrative of various stages in the fabrication pocket dopant regions having indium ions in accordance with the first embodiment of the present invention; and

FIGS. 4A to 4D show cross-sectional views illustrative of various stages in the fabrication the pocket dopant regions of the nitride read only memory with indium ions in accordance with the second embodiment of the present invention.

### DESCRIPTION OF THE PREFERRED EMBODIMENT

Preferred embodiments of the present invention will now be described in greater detail. Nevertheless, it should be recognized that the present invention can be practiced in a wide range of other embodiments besides those explicitly described, and the scope of the present invention is expressly not limited except as specified in the accompanying claims.

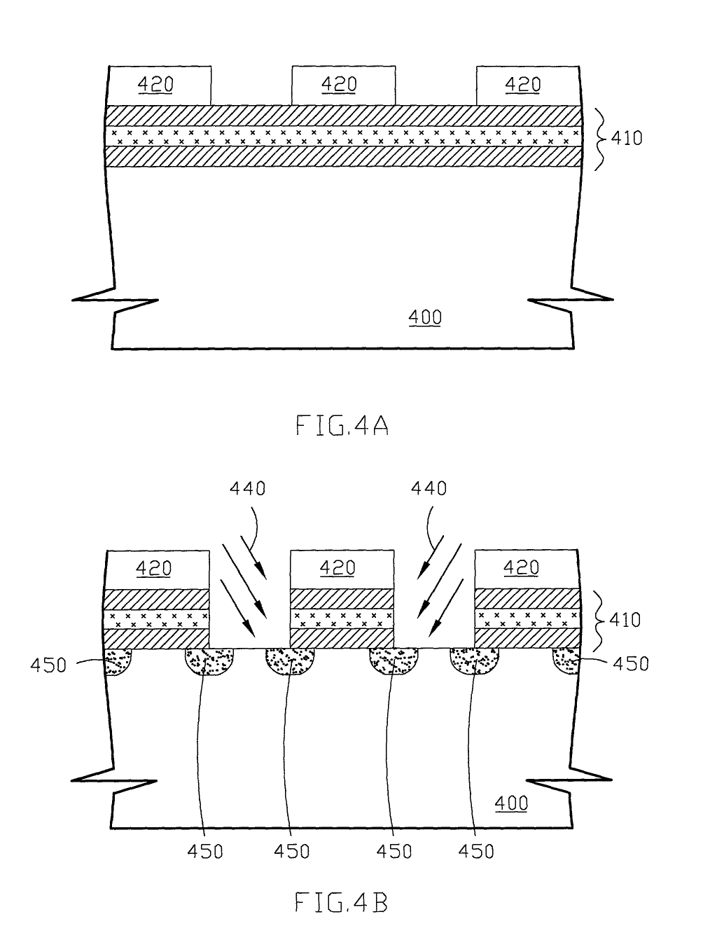

As illustrated in FIG. 3A, in the first embodiment of the present invention, first of all, a P-type semiconductor substrate 300 is provided. Then a dielectric layer 310, such as a stack dielectric layer, is formed on the P-type semiconductor substrate 300, wherein the method for forming the dielectric layer 310 comprises a depositing process. Afterward, a photoresister layer 320 is formed and defined on the dielectric layer 310. Perform a N-type ion-implanting process 330 by way of using the photoresister layer 320 as an ion-implanting mask to form a source/drain region 340 in the P-type semiconductor substrate 300, wherein the source/drain region 340 is separated at a predetermined distance as a channel 350 from each other. Subsequently, perform a pocketed ion-implantation 360 at least one time by way of using the photoresister layer 320 as the ion-implanting mask to form at least one pocket dopant regions 370 at the channel 350 close to beside the source/drain region 340, wherein the pocket dopant of the pocket ion-implantion 360 comprises an indium ion, as shown in FIG. 3B.

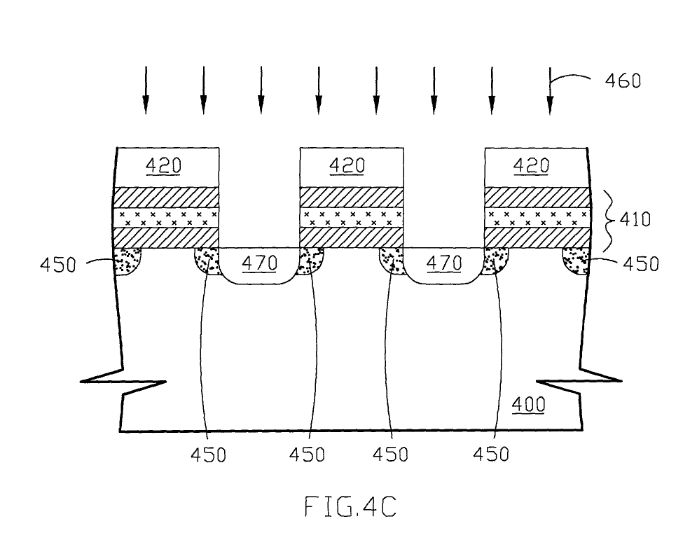

As illustrated in FIG. 4A to FIG. 4C, in the second embodiment of the present invention, first of all, a P-type semiconductor substrate 400 is provided. Then an oxide-nitride-oxide layer (ONO) 410 is formed on the P-type semiconductor substrate 400. Afterward, a plurality of photoresister regions 420 are formed on the oxide-nitride-oxide layer 410. The oxide-nitride-oxide layer 410 is then etched by way of using an etching process with a plurality of photoresister regions 420 as a plurality of etching masks to form a plurality of nitride read only memory cells 430 (NROM). Subsequently, perform a poketed ion-implantation 440 at least two times by way of using the plurality of photoresister regions 420 as the plurality of ion-implanted masks to form a plurality of pocket dopant regions 450 under the plurality of nitride read only memory cells 430, respectively, wherein the poketed ion-implantation 440 uses the indium ions as the poketed dopant. Next, perform a N-type ion-implanting process 460 by way of using the plurality of photoresister regions 420 as the plurality of ion-implanted masks to form a plurality of ion-implanting regions 470 in the P-type semiconductor substrate 470 between the plurality of nitride read only memory cells 430. Finally, the plurality of photoresister regions 420 are removed to form an nitride read only memory.

In these embodiments of the present invention, as discussed above, a method for fabricating the read only memory having multi-bits is provided. This invention can perform an ion-implanted process with the indium ions (In), so as to substitute for boron ions and avoid defect of boron ions, which is easy to diffuse. Therefore, the present invention is appropriate for deep sub-micron technology to provide the semiconductor devices. Furthermore, The present invention can also form the pocket dopant regions by the ion-implanted process with the indium ions. On the other hand, this invention can much reduce the lateral distribution of pocket dopant with boron ions due to the indium ions are difficult to diffuse. In other wards, for scaled nitride read only memory devices and multi-bits per cell operation, the pocket dopant of indium ions can reduce pocket distribution and, then, reduce the electron distribution in silicon nitride along the channel during hot electron programming. Hence, the method of the present invention can increase yield and quality, so that reduce process cost. Thus, the present invention can correspond to economic effect.

Of course, it is possible to apply the present invention to the nitride read only memory process, and also it is possible to the present invention to any one read only memory in the semiconductor devices. Also, this invention can be applied to indium ions as the pocket dopant concerning the pocket ion-implanted process used for forming the read only memory have not been developed at present. Method of the present invention is the best read only memory compatible process for deep sub-micro process.

Obviously, many modifications and variations of the present invention are possible in light of the above teachings. It is therefore to be understood that within the scope of the appended claims, the present invention may be practiced otherwise than as specifically described herein.

Although specific embodiments have been illustrated and described, it will be obvious to those skilled in the art that various modifications may be made without departing from what is intended to be limited solely by the appended claims.

What is claimed is:

1. A method for forming a pocket dopant region of an indium ion, the method comprising:
providing a P-type semiconductor substrate;
forming a dielectric layer on said P-type semiconductor substrate;
forming and defining a photoresister layer on said dielectric layer;
performing a N-type ion-implanting process by way of using said photoresister layer as an ion-implanting mask to form a N-type ion-implanting region in said P-type semiconductor substrate; and
performing a pocketed ion-implantation with an indium ion by way of using said photoresister layer as said ion-implanting mask to form said pocket dopant region of said indium ion closed to beside said N-type ion-implanting region.

2. The method according to claim 1, wherein said dielectric layer comprises a stack dielectric layer.

3. The method according to claim 2, wherein said stack dielectric layer comprises a oxide-nitride-oxide layer.

4. The method according to claim 1, wherein the method for forming said dielectric layer comprises a depositing process.

5. The method according to claim 1, wherein said N-type ion-implanting region comprises a source/drain region.

6. A method for forming a read only memory, the method comprising:
providing a P-type semiconductor substrate;
forming a dielectric layer on said P-type semiconductor substrate;
forming and defining a plurality of photoresister layers on said dielectric layer to expose a portion of said dielectric layer;
performing a pocketed ion-implantation with an indium ion at least one time by way of using said plurality of photoresister layers as a plurality of ion-implanting masks to form a plurality of pocket dopant regions having said indium ion in said P-type semiconductor substrate; and
performing a N-type ion-implanting process by way of using said plurality of photoresister layers as said ion-implanting masks to form a plurality of N-type ion-implanting regions in said P-type semiconductor substrate between said plurality of photoresist layers; and
removing said plurality of photoresist layers to form said read only memory.

7. The method according to claim 6, wherein said dielectric layer comprises an nitride layer.

8. The method according to claim 6, wherein the method for forming said dielectric layer comprises a depositing process.

9. The method according to claim 6, wherein said plurality of pocket dopant regions having said indium ion are located in said P-type semiconductor substrate beside said plurality of N-type ion-implanting regions.

10. The method according to claim 6, wherein said plurality of N-type ion-implanting regions comprises a plurality of source/drain regions.

11. A method for forming a read only memory, the method comprising:
providing a P-type semiconductor substrate;
forming a dielectric layer on said P-type semiconductor substrate;
forming and defining a plurality of photoresister layers on said dielectric layer to expose a portion of said dielectric layer;
performing an etching process by way of using said plurality of photoresister layers as a plurality of etching masks to etch said dielectric layer and form a plurality of memory cells;
performing a pocketed ion-implantation with an indium ion at least two time by way of using said plurality of photoresister layers as a plurality of ion-implanting masks to form a plurality of pocket dopant regions having said indium ion beside said P-type semiconductor substrate under said plurality of memory cells; and
performing a N-type ion-implanting process by way of using said plurality of photoresister layers as said ion-implanting masks to form a plurality of N-type ion-implanting regions in said P-type semiconductor substrate between said plurality of memory cells; and
removing said plurality of photoresist layers to form said read only memory.

12. The method according to claim 11, wherein said dielectric layer comprises an nitride layer.

13. The method according to claim 11, wherein the method for forming said dielectric layer comprises a depositing process.

14. The method according to claim 11, wherein said plurality of pocket dopant regions having said indium ion are located in said P-type semiconductor substrate beside said plurality of N-type ion-implanting regions.

15. The method according to claim 11, wherein said plurality of N-type ion-implanting regions comprises a plurality of source/drain regions.

16. A method for forming an nitride read only memory, the method comprising:
providing a P-type semiconductor substrate;
forming an oxide-nitride-oxide layer on said P-type semiconductor substrate;
forming and defining a plurality of photoresister layers on said oxide-nitride-oxide layer to expose a portion of said oxide-nitride-oxide layer;
performing an etching process by way of using said plurality of photoresister layers as a plurality of etching masks to etch said oxide-nitride-oxide layer and form a plurality of read only memory cells;
performing a N-type ion-implanting process by way of using said plurality of photoresister layers as an ion-implanting masks to form a plurality of N-type ion-implanting regions in said P-type semiconductor substrate between said plurality of read only memory cells;
performing a pocketed ion-implantation with an indium ion at least two time by way of using said plurality of photoresister layers as said plurality of ion-implanting masks to form a plurality of pocket dopant regions having said indium ion beside said P-type semiconductor substrate under said plurality of memory cells; and
removing said plurality of photoresist layers to form said nitride read only memory.

17. The method according to claim 16, wherein the method for forming said oxide-nitride-oxide layer comprises a depositing process.

18. The method according to claim 16, wherein said plurality of N-type ion-implanting regions are separated by a channel from each other.

19. The method according to claim 16, wherein said plurality of N-type ion-implanting regions comprises a plurality of source/drain regions.

20. The method according to claim 16, wherein said plurality of pocket dopant regions having said indium ion are located in said P-type semiconductor substrate beside said plurality of N-type ion-implanting regions.
